(19) United States
(12) Patent Application Publication
(10) Pub. No.: US 2026/0086179 A1
(43) Pub. Date: Mar. 26, 2026

(54) METHOD OF ANALYSING INVERSION RECOVERY MAGNETIC RESONANCE IMAGES

(71) Applicant: PERSPECTUM LIMITED, Oxford (GB)

(72) Inventors: Matthew ROBSON, Oxford (GB); Carolina FERNANDEZ, Oxford (GB); Alex SMITH, Oxford (GB)

(73) Assignee: PERSPECTUM LIMITED, Oxford (GB)

(21) Appl. No.: 19/102,758

(22) PCT Filed: Aug. 7, 2023
(86) PCT No.: PCT/EP2023/071834

§ 371 Date: Feb. 10, 2025

(30) Foreign Application Priority Data
Aug. 10, 2022 (GB) 2211687.5

(51) Int. Cl. G01R 33/48; G01R 33/50; G01R 33/56; G01R 33/561

(52) U.S. Cl. CPC G01R 33/4828; G01R 33/50; G01R 33/5608; G01R 33/5616

(57) ABSTRACT

A method of analysing MRI images is described. The method comprising acquiring at least three medical MR images of a subject; analysing the at least three medical MR images to determine a water T1 map; applying a field strength correction and an iron correction to the determined water T1 map to generate a corrected water T1 map; generating one or more simulated MRI images based on the water T1 map; fitting the one or more simulated MR images to determine a standard cT1 image for the subject.

### FIELD OF THE INVENTION

This invention relates to a method of analysing Magnetic Resonance Imaging (MRI) images, to generate a synthetic MR signal relaxation curve, using multiple images that may be acquired from a range of different MRI scanners. Where the terms “LiverMultiScan”, “Siemens”, “Matlab” and “Mathworks” are used, these are acknowledged as registered trade marks.

### BACKGROUND

Magnetic Resonance Imaging (MRI) scanning technology can be used to acquire images of the human body that have a contrast that is dependent upon the nuclear magnetic resonance (NMR) relaxation properties of the imaging nucleus (typically the Hydrogen atoms in water and fat). It has been known for a long time that these depend on the environment of the atoms yielding these spin properties. The T1, T2 and T2* properties (for example) depend on the magnetic environment of the atoms and also upon the motion of these molecules within this environment.

In non-viscous liquids (such as cerebrospinal fluid (CSF) for example) the hydrogen nuclei of water have long T1 and T2 owing to the uniform magnetic field environment and the rapid unhindered motion of the water molecules. Protons that are bound or interact with proteins have hindered motion and can have much shorter T2 and T1. These relaxation properties have been found to be useful as the ensemble average fluid environment of hydrogen nuclei in fats and water are frequently different in diseased than in healthy tissues.

By collecting a series of images that show the same anatomy but with image contrast with different sensitivity to these relaxation properties it is possible to create parametric maps of the relaxation properties. There are a few challenges to this:

Firstly, the data acquisition is challenging in tissues of the abdomen owing to the dual challenges of cardiac and respiratory motion as the images that are collected benefit from being absolutely aligned. The acquisitions and processing must manage this motion through methods such as; freezing the motion, correcting for the effects of motion, or redundancy of acquisition and throwing away erroneous data.

Secondly, extracting the parametric maps from the images with different contrast can be difficult. This difficulty can be due to the level of noise in the data, the small number of datapoints, complications in the fitting function due to imperfect acquisition or confounding sources of MRI signal intensity.

The applicants have pioneered the use of a T1 based imaging contrast based on T1 as determined by the MOLLI method (MOdified Look-Locker Inversion recovery). This is described in GB2498254 and Messroghli D R, Radjenovic A, Kozerke S, Higgins D M, Sivananthan M U, Ridgway J P. Modified Look-Locker inversion recovery (MOLLI) for high-resolution T1 mapping of the heart. Magn Reson Med 2004; 52:141-146. As iron in the body affects T1, and iron concentration in the liver is highly variable the applicants have used a pioneering approach that corrects the T1 for the concentration of iron present in each liver. The applicants call this metric cT1 (corrected T1) and the LMS (LiverMultiScan®) product determines maps of cT1 in human livers that are normalised to a standard level of liver iron. T1 is also dependent on the magnetic field strength of the MRI scanner (typically 1.5 T and 3 T scanners are used). The measurements are standardised to what would be achieved on a 3 T scanner. Finally, there are some subtle differences between MRI scanners from different manufacturers, therefore values discussed herein are all standardized to measurement on a Siemens® 3 T scanner. Having a standardized measurement that can be determined for a patient using any of the commercially available scanners that is stable and robust is an important cornerstone for commercial offerings as it potentially enables statements that can be made such as “if your cT1 is above 850 ms then you are in a population that would benefit from a particular treatment” without standardization this simplification is not possible. Parametric mapping using MRI is an intrinsically complicated approach, but it needs to be used in an environment where it needs to be delivered in a simple way, the development of a standardized metric with the potential to deliver ranges for the parameter that lead into stratification decisions (e.g. cT1>825 ms indicates disease and hence the patient should get the drug), which can be used at any MRI centre in the world and is an attractive and scalable technology.

FIG. 1 shows a standardized cT1 map derived using the 1.5 T MOLLI acquisition with regions of interest highlighted in the figure.

FIGS. 2(a)-2(c) shown images representing cT1, T2* and PDFF (proton density fat fraction) values obtained using different image acquisition methods. The T2* and PDFF images are acquired with the multi-echo spoiled gradient echo acquisition. The cT1 is derived from MOLLI and T2* data.

It should be noted that whilst cT1 is standardized it isn't a good (in a metrological sense) measurement of T1. The MOLLI approach to measurement of T1 depends not just on T1 (as it should) but also on T2, magnetization transfer, the level of fat in the tissue (PDFF, proton density fat fraction, reported as a percentage of signal from fat compared to the signal from fat+water) and other influences. These deficiencies come from the use of the MOLLI acquisition, which is required to collect data within the time of a short breath-hold and to be gated to the cardiac cycle (this approach can be used in a non-gated fashion in some cases too).

While cT1 is imperfect, it has been used in many studies. This means that it has been validated against biopsy, prognostically and in several clinical trials, therefore whilst it is without a doubt imperfect it does represent something of a standard. Therefore, cT1 is a metric that is of great interest as it has clear relevant correlates even though it is not scientifically pure from an MR physics perspective. It takes many studies to confirm a threshold (such as the 825 ms defined above) and so without a stable method this becomes impossible.

Conventionally cT1 can only be determined from a MOLLI acquisition but there are limitations to this, for example:
If the MRI scanner doesn't have the MOLLI acquisition method;
If the MRI scanner is unable to support the particular timings needed for the MOLLI sequence to enable accurate cT1 measurement;
If the user is interested in 3D coverage of the liver (MOLLI is a 2D sequence and consequently collecting a 3D volume would require many breath-holds which would be impractical);
If the user is interested in collecting very high spatial resolution information (not supported by MOLLI acquisitions);
If the MOLLI sequence couldn't be used because of problems with breath-holding;
If the MOLLI sequence was unreliable owing to spatial variations in B1+ (the RF excitation field) or B0 (the uniformity of the static magnetic field).

In these situations, the user may want the information of the cT1 map, but would not be able to enable it using the conventional MOLLI based approach.

### SUMMARY OF THE INVENTION

According to examples of the invention there is provided a method of analysing MR images comprising: acquiring at least three medical MR images of a subject; and a reference MR image of the subject acquired without the use of an inversion pulse, analysing the at least three medical MR images to determine a water T1 map; applying a field strength correction and an iron correction to the determined water T1 map to generate a corrected water T1 map; generating one or more simulated MRI images based on the water T1 map; and fitting the one or more simulated MR images to determine a standardized cT1 image for the subject.

In a preferred example embodiment of the invention the standardized cT1 image is a cT1 image corrected for an image acquired on a reference MRI scanner for a subject with normal iron levels.

Further preferably, the simulated MR images are generated using data from a dictionary of synthetic MR signal relaxation curves.

In an example embodiment of the invention the data in the dictionary of synthetic MR signal relaxation curves is selected to match at least one of the corrected water T1 map and a PDFF map for the acquired medical MR images.

Preferably, each of the acquired medical MR images comprise pairs of images with the same inversion time. Further preferably, each successive medical MR image has a longer inversion time than the previously acquired medical MR image. In an example embodiment of the invention the minimum value for the inversion time of the first medical image is between 0.010-1.0 seconds.

In a preferred example embodiment of the invention, the at least three medical MR images comprises eight MR images.

Preferably, the at least three medical MR images are acquired so that there will be redundant MR images.

In an example embodiment of the invention, the at least three medical MR images are inversion recovery MR images.

Preferably, one or more of the at least three medical MR images is acquired without the use of an inversion pulse.

In a preferred example embodiment of the invention, the plurality of acquisition medical MR images are acquired using a single shot acquisition. Further preferably, the single shot acquisition comprises at least one of: EPI or single shot fast echo.

In an example embodiment of the invention the field strength correction and iron correction to generate a corrected water T1 map use a forward Bloch simulation. Further preferably, the forward Bloch simulation has inputs comprising one of more of PDFF value, T2* value, water T1 value, a pulse sequence for the MRI scanner used to acquire the medical MR images. Preferably, the field strength correction is based on modification of the nominal field strength used for the acquisition of the at least three medical inversion recovery MR images. Further preferably, the iron correction corrects for differences in the iron concentration from a normal level using at least one of a T2* map and a B0 field strength.

In a preferred example embodiment of the invention the analysis of the plurality of medical MR images results in a composite image.

In a further example embodiment of the invention, the water T1 map is determined for the composite image.

Further, preferably the single inversion pulse is an adiabatic pulse.

In an example embodiment of the invention the method further comprises the steps of acquiring further medical MR images immediately before or after the acquisition of the plurality of medical MR images. Preferably, the further medical MR images are multi-echo spoiled gradient echo acquisition images.

In a preferred example embodiment of the invention, the original MRI images are acquired at 0.3-3.0 T.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 shows a cT1 map derived using the 1.5 T MOLLI prior art method.

FIG. 2(a) shows a cT1 image slice acquired with the prior art MOLLI method;

FIG. 2(b) shows a T2* image slice acquired with the prior art MOLLI method; and

FIG. 2(c) shows a PDFF image slice acquired using the prior art MOLLI method.

FIG. 3(a)-(d) shows the raw data for images acquired at different inversion times (T1) according to an example embodiment of the invention; and

FIG. 3(e) shows an uncorrected T1 map, with T1 values in milliseconds (ms) according to an example embodiment of the invention.

FIG. 4 shows a water T1 (water T1) for the subject of the composite image of FIG. 1.

FIG. 5 shows the cT1 map derived from the images in FIGS. 4 and 2b and 2c.

FIG. 6 is a flow chart showing the various method steps in a preferred example embodiment of the invention.

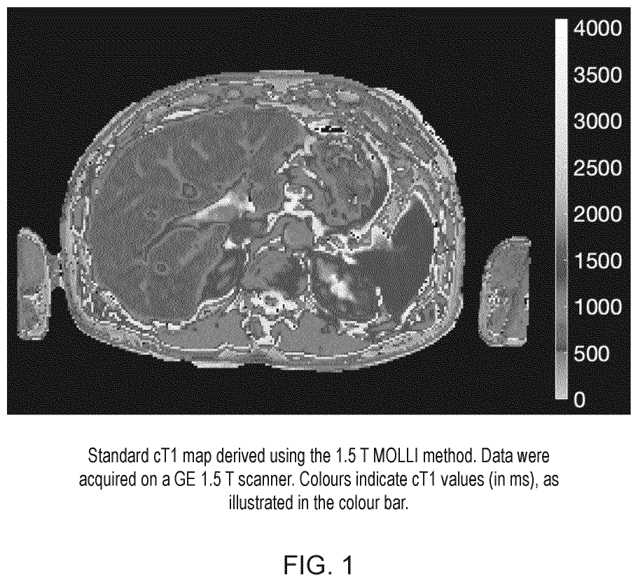

### DETAILED DESCRIPTION

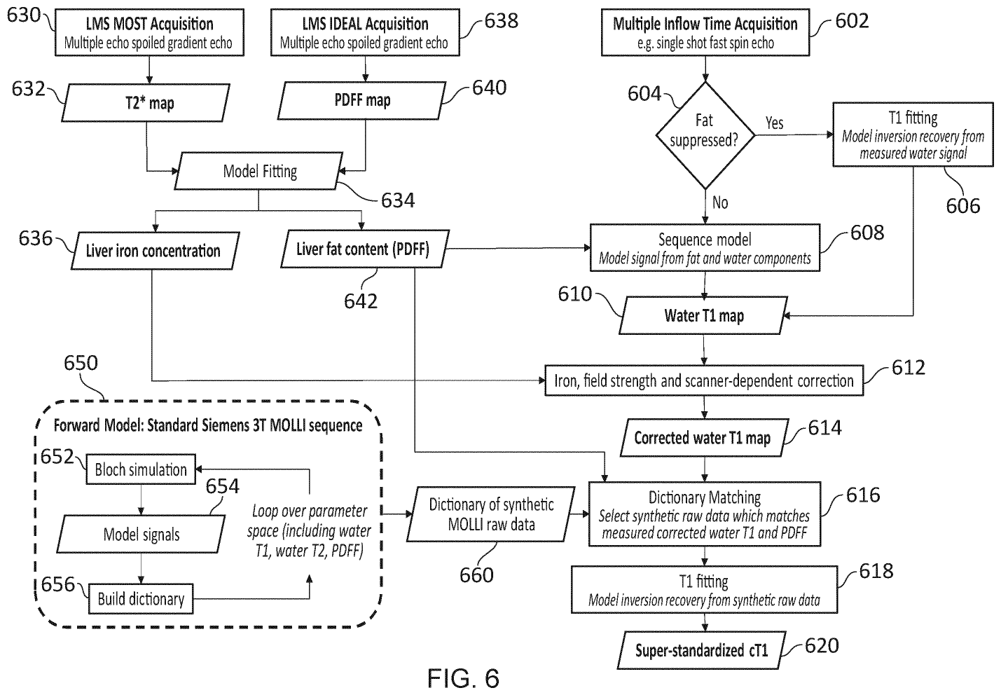

The present invention will now be described with reference to the accompanying drawings in which there is illustrated an example of a method and apparatus for generating a synthetic cT1 MR image from a plurality of acquired MR images. Preferably, the MR images are inversion recovery images. However, it will be appreciated that the present invention is not limited to the specific examples herein described and as illustrated in the accompanying drawings. FIG. 6 is a flow chart showing steps of the method in a preferred example embodiment of the invention

In this first example embodiment of the invention a GE 1.5 T MRI scanner and a GE 3 T scanner were each used to acquire a 2D water T1 map, although other MRI scanners with different nominal magnetic field strengths may also be used. For example, the MRI scanner may operate between 0.3-3 T. The methods by which this was performed were as follows. The subject was placed in the MRI scanner and preferably imaged using phased array abdominal coils, although other imaging coil arrays may also be used.

In an example embodiment of the invention, a single-shot fast spin echo (IR SS-FSE) acquisition is used to acquire a medical image as an acquisition image, preferably an MRI scan of a subject as shown in step 602. Other acquisition methodologies may alternatively be used, for example echo planar imaging (EPI). In this preferred example embodiment of the method, a fast 2D spin-echo medical MR image was acquired in a single shot, after a preparatory inversion pulse. In a preferred example embodiment of the invention, the acquisition is fat suppressed, as shown in step 604. If fat suppression is used, then a T1 fitting step is performed at 606 to model inversion recovery from the measured water signal. The method then proceeds directly to step 610 for generation of a water T1 map. If there is no fat suppression during the MR image acquisition, for the acquisition images, then step 608 uses a sequence model to model the signal from fat and water components, and the sequence model is used for the generation of the water T1 map at 610.

For a fast 2D spin-echo acquisition ‘Half-Fourier’ imaging was used to reduce the MR image slice acquisition time, in which just over half (typically 63%) of k-space data was directly acquired, with the remaining k-space lines estimated based on phase-conjugate symmetry (by the MRI scanner). However other imaging methodologies may also be used, the advantage of “half-Fourier” with Single Spin-Fast Spin Echo is that this methodology yields very high signal to noise and limited unwanted T2 weighting. It would alternatively be possible to use full k-space imaging.

Preferably, the method requires the acquisition and analysis of at least three medical images (MR images) of a subject. In a preferred example embodiment of the invention, the method requires the acquisition and analysis of eight MRI scans of the subject (the acquisition images). Multiple MRI scans are acquired so that there will be redundant MR images for the analysis. In an example embodiment of the invention, the at least three medical MR images are inversion recovery MR images.

In an example of the invention, five MR image slices (each of 8 mm thickness with 15 mm slice spacing) were acquired in a single breath hold, using a repetition time (TR) in the range 500 ms to 20 s. Preferably, the TR is 2000 msec, and effective echo time 35-40 msec. In an example embodiment of the invention the echo time is minimised and is preferably in the range 1-100 msec, so that the signal to noise is maximised. MR Image acquisitions with the parameters described above yielded data with a resolution of 1.72×1.72×8 mm reconstructed at a resolution of 0.86×0.86×8 mm. In a preferred example embodiment of the invention, the plurality of acquisition MR images are acquired using a single shot acquisition. Preferably, the single shot acquisition comprises at least one of Echo Planar Imaging EPI or single shot fast spin echo acquisition. In an example embodiment of the invention, one or more of the at least three medical MR images is acquired without the use of the inversion pulse.

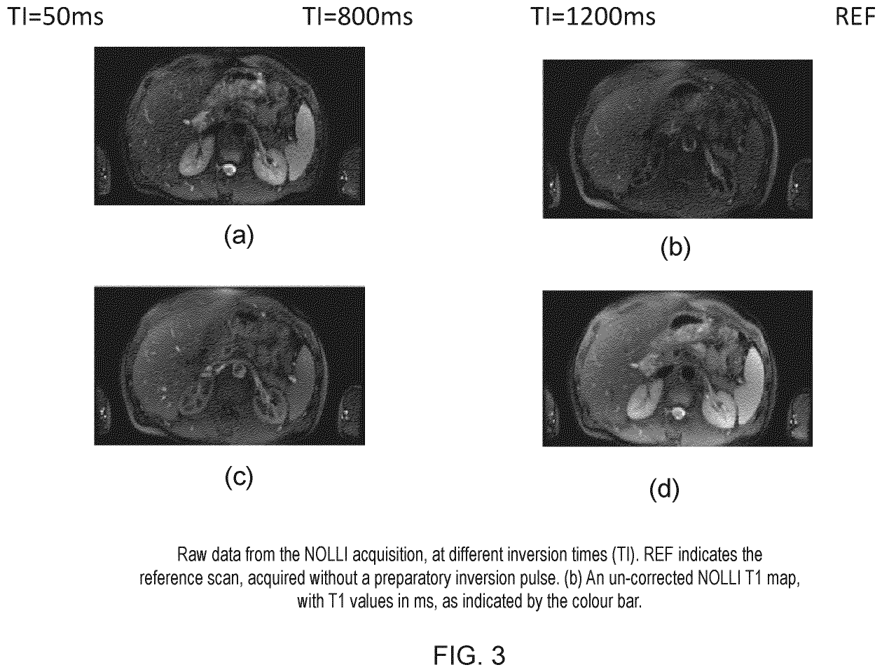

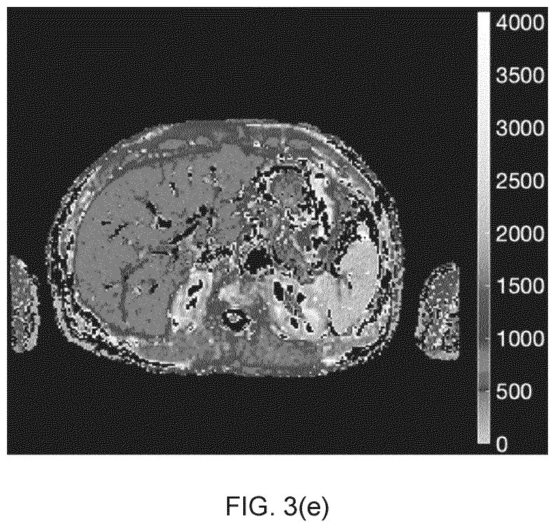

The above single breath hold medical MR scan acquisitions were repeated over a range of inversion times (TIs) as shown in FIGS. 3(a) to 3(d). FIG. 3(a) shows a medical MR image acquired with TI=50 ms, at 1.5 T, 3(b) shows a medical MR image acquired at 800 ms and 1.5 T, FIG. 3(c) shows a medical MR image acquired with TI=1200 msec, and FIG. 3(d) is a medical MR image acquired without a preparatory inversion pulse.

In the example of the invention as shown the shortest TI was 50 msec at 1.5 T as shown in FIG. 3(a), and 75 msec at 3 T (not shown). Other inversion times and field strengths may also be used in alternative example embodiments of the invention. In an example of the invention the minimum value of TI for the first medical MR image is in the range 0.01 to 1.0 seconds. At both example field strengths (1.5 T and 3.0 T), the first medical MR image was followed (at both field strengths) by at least two subsequent medical MR images acquired with TIs of 800 ms (FIG. 3(b) and 1200 ms (FIG. 3(c)), and then a reference medical MR scan (FIG. 3(d)) acquired without a preparatory inversion pulse (effectively TI=near infinite).

In an example of the invention, a set of four medical MR image acquisitions, with different TI values, were acquired twice (requiring 8 breath holds in total), to give a total of eight medical images. Preferably, each of the acquired medical MR images comprises pairs of images with the same inversion time. Acquiring such multiple MR images provides redundancy in the data, and increases the robustness of the acquired MR images to motion-related artefacts in post-processing. Different schemes can be used that include combination of more or fewer repetitions of the same acquisition, more or fewer different Inversion times (TI), and the selection of a dataset with or without the non-inverted acquisition, as long as at least three MR medical images are acquired for subsequent analysis. In an example of the invention, each successive acquired medical MR image has a longer inversion time than the previously acquired medical MR image. These allow the characteristics of the final map to be fine-tuned depending on whether acquisition time, spatial resolution or noise reduction is being prioritized for the MR image acquisition.

Typically, TI is in the range from 50 ms to 2000 ms, with an additional reference medical MR image scan with very long TI, and the TI value for each of the four medical MR images is different. Preferably, TI will increase for each subsequent medical MR scan. The values of TI are designed to optimise the sensitivity to changes in the T1 of the particular tissue of interest. Thus, in a preferred example embodiment of the invention each of the medical MR images has a unique inversion time, and each successive medical MR image in the sequence of MR images acquired in one acquisition session has a longer inversion time than the previously acquired medical MR image. Preferably, the method may further comprise the steps of acquiring further reference medical MR images immediately before or after the acquisition of the plurality of medical MR images. Preferably, the further medical MR images are multi-echo spoiled gradient echo acquisition images.

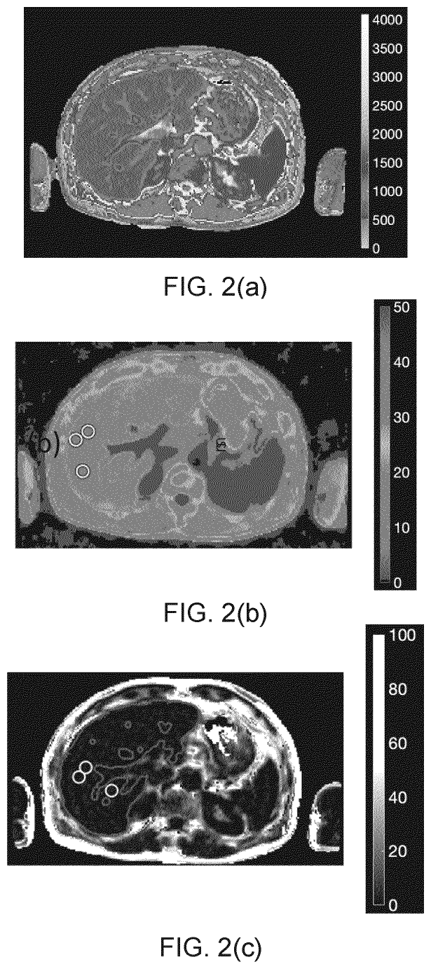

For comparison of the method in the invention with the prior LMS (LiverMultiScan®) methods, the standardized MR images required for an LMS (LiverMultiScan®) acquisition were also collected (i.e. MOLLI-T1, LMS-MOST (for iron) [a multi-echo spoiled gradient echo acquisition], LMS-IDEAL (used for fat in this case) [a multi-echo spoiled gradient echo acquisition]), see for example https://doi.org/10.1002/jmri.20831. Step 630 on FIG. 6 shows the LMS most acquisition, for iron, which results in a T2* map at step 632. The IDEAL acquisition, used for fat is shown at step 638, and results in a PDFF map at step 640. At step 634 the T2* map and PDFF map are fitted to a model at step 634. The T2* image of FIG. 2(b) is an image that results from steps 630 and 632 of FIG. 6, and the PDFF image as shown in FIG. 2(c), is the image that results from steps 638 and 640 of FIG. 6. Step 636 is the determination of the liver concentration, and step 642 is determination of the liver fat content from the PDFF.

In a preferred example embodiment of the invention the LMS most acquisition at step 630 was acquired using a 5-(1)-1-(1)-1 acquisition scheme with 35 deg excitation pulses and a balanced bSSFP (balanced steady state free precession) readout, the acquisition was cardiac gated with a slice thickness of 6 mm and acquisition required around 10 seconds (less than the time for 10 heart-beats) using the shMOLLI acquisition (although not the shMOLLI processing) [ref https://patents.google.com/patent/US20120078084A1/en FIG. 2B and/or https://jcmr-online.biomedcentral.com/articles/10.1186/1532-429X-12-69].

The LMS-MOST acquisition at step 630 acquires thin slice (3 mm) spoiled gradient echo MR images with multiple echo times. It is designed specifically to measure the T2* in the liver and is robust to breathing and B0 artefacts through the use of multiple repetitions of the same image (preferably 7 repetitions at 1.5 T) that are selectively combined to minimise variance and by using a thin slice that helps reduce the effects of through slice dephasing, the imaging time for the LMS-MOST acquisition is around 10 seconds.

The LMS-IDEAL acquisition at step 638 also uses a multiple echo spoiled gradient echo MR image acquisition with a low excitation flip angle to minimise differential T1 weighting between the fat and water species and so yield a precise PDFF map (after processing) at step 640. Preferably, the acquired medical MR images will use the presence or absence of inversion pulses and adjustment of the inversion time relative to the inversion pulse to modulate the signal intensity. Preferably there will be multiple different times between the inversion pulse and the acquisition (the ‘inversion time’) with the first time-delay being less than 0.5 second. Preferably the acquisition should use a single-shot acquisition (either EPI or single-shot Fast Spin Echo) to minimise image artefacts due to motion. Preferably there should also be an image that uses the same acquisition module but doesn't include an inversion pulse. Preferably there should be multiple redundancy in the acquisition such that more images are collected than parameters that are fit. Preferably multiple slices should be imaged in each breath-hold each of these images with the same image contrast.

In an example embodiment of the invention fat suppression should be used in the acquisition (ref https://mriquestions.com/uploads/3/4/5/7/34572113/haase_frahm_chess.pdf) to eliminate the signal from the fat from the images. This is shown at step 604 of FIG. 6. In a second example embodiment of the invention water excitation should be used (using an excitation pulse that is designed to excite that water and not fat, these are typically binomial RF pulses) [ref https://mriquestions.com/uploads/3/4/5/7/34572113/water_excitation_radiol_2e2243011227.pdf] in the acquisition to eliminate the signal from the fat. In other embodiments other techniques of fat suppression (e.g., DIXON [ref https://pubmed.ncbi.nlm.nih.gov/6089263/] and/or fat suppression) might be used to reduce the fat signal from the data.

In an example embodiment of the invention data are collected for medical MR images that are acquired over 8 separate breath-holds. Preferably, four different MR image contrasts are collected using fat suppressed single-shot fast-spin-echo acquisitions and the acquisition of these 4 contrasts is repeated. Preferably, claim wherein each of the acquired medical MR images comprise pairs of images with the same inversion time. In a preferred example of the invention, each successive acquired medical MR image has a longer inversion time than the previously acquired medical MR image. Further preferably, the minimum value for the inversion time of the first medical MR image is between 0.010-1.0 seconds. The image contrast in the 4 contrasts spans a range of ‘inversion times’, in one of the 4 images no inversion pulse is applied. Preferably, the type of RF pulse used for the inversion pulse is an ‘adiabatic pulse’ which ensures consistent inversion of the magnetization that is robust to small variations in B1+ and B0. In a preferred example embodiment of the invention the single inversion pulse is an adiabatic pulse [ref: https://mriquestions.com/uploads/3/4/5/7/34572113/tannus-adiabaticpulses.pdf]. An example of an inversion pulse for this purpose would be a 10 ms duration hyperbolic secant pulse.

In an example embodiment of the invention medical image data for the plurality of medical images are collected with Echo Planar Imaging, EPI (instead of single-shot fast-spin-echo).

Processing of these medical MR images may involve pre-processing which evaluates the effects of breathing on the data. Processing of these MR images may involve a registration step to reduce the impact of patient motion and aligns the images to compensate for patient motion. Typically, this will optimise a cost function through realistic spatial transformations of the image data. One possible method to achieve this is to apply a registration algorithm to each pair and to estimate the level of displacement locally in parts of field-of-view or globally across the whole field-of-view. Another method can be to generate maps of local similarity or dissimilarity for pairs of images. This approach can reduce the errors in the T1 maps that would occur from motion that occurs within the plane of the image acquisition. Estimates of motion may be used to determine which data to include in a per-pixel model fit and which data to exclude as part of a data subset-selection strategy. Motion estimates may also be used to define a check on the entire set of acquired data to determine whether a minimum feasible set is available for successful fitting or whether the data set should be rejected in its entirety.

Processing of these MR images may also involve a step that rejects certain images from the final analysis to reduce the impact of patient motion. Calibration may be carried out for setting tolerance thresholds for the level of motion that is acceptable with respect to any subsequent per-pixel model fitting for water T1. Rejection of images may be applied when large through plane motions occur and hence the tissue being sampled is not the same from image to image, this is different to the in-plane motion effects. To detect and reject through plane motion similarity metrics are used when two or more images are compared. Images that are found to be outliers compared to the other images in the context of these similarity metrics will be rejected leaving a set of images that are consistently of the same slice. A further approach may utilise a separately acquired 3D dataset to evaluate slice motion and alignment, this 3D acquisition would provide a reference to which data can be compared and registered. Typically, 0, 1 or 2 images will be rejected, rejecting large numbers of images results in poor data fitting as the fitting may become poorly conditioned.

These processed MR images will be used in the next fitting step. It may be that no processing is needed on some datasets i.e., when there is no patient motion or the patient motion is not significant.

Uncorrected (i.e., not corrected for iron) water T1 maps will be generated from plurality of medical MR images (preferably at least three medical MR images) using a single or multiple slice pixel-by-pixel fitting approach using the formula:

$$S ( TI , x , y , z ) = A ( x , y , z ) + B ( x , y , z ) \cdot exp ( - TI / water T 1 ( x , y , z ) ) + epsilon ( TI , x , y , z )$$

Where S(TI,x,y,z) is the signal intensity in an image at spatial coordinate x,y,z and TI is the inversion time in the image being fitted.

Where: A and B are fitting parameters that vary as a function of image position.

water T1(x,y,z) is the uncorrected water T1 as a function of position in the data.

Epsilon is a noise term that is minimised in the fitting, typically using a least-square error criteria.

Fitting may be performed on the magnitude/absolute value of S(TI,x,y,z) or on the complex value of S(TI,x,y,z). In the present embodiment we fit in the magnitude domain.

In the case of the medical MR image where no inversion pulse is applied, the TI is set to a very large time such that the exponent term equals zero. For each spatial location (pixel coordinate) data fitting is performed by modelling the signal for each TI. The fitting may be performed in complex number space in which case A and B will include a phase angle term that will vary with image position. The fitting may be performed in the magnitude domain with the data and fitting functions both undergoing a magnitude transformation.

In an alternative example of the invention NOLLI_water T1 (water T1 as determined by the NOLLI method) was determined by simulating the forward Bloch simulation and selecting the water T1 that best explain the data.

Preferably, the method of the invention also comprises the steps of acquiring further medical MR images immediately before or after the acquisition of the first and second medical MR images. Preferably, the further medical MR images are multi-echo spoiled gradient echo acquisition MR images.

In an example embodiment of the invention, the MR images are acquired at 0.3-3.0 T.

In an example embodiment of the invention, for the 8 breath-hold NOLLI_water T1 dataset, the data were read into Matlab®) (Mathworks®), Natick, MA) and fit to the equation above in the magnitude domain by minimizing the least square error at each image location. Other example embodiments of the invention may use alternative software to analysis the medical image data.

FIG. 3 shows the output from NOLLI acquisition of the first example embodiment of the invention, and initial processing of the plurality of medical MR images to produce a composite image for the subject. Preferably, the water T1 map is determined for the composite image. The uncorrected NOLLI-T1 map was determined using Equation (1). Bloch equation simulations can be used to fit the data that simulate the magnetization vectors for different T1 values based on the actual pulse sequence that has been used. In this case, this approach was not used but an alternate example embodiment of the invention could involve the approach of optimising the T1 in a Bloch simulation of the pulse sequence and selecting the T1 that yields simulated data, such as simulated MR medical images, that is most similar to the scanner acquired data.

The PDFF map may be calculated from a single MR image slice, a single voxel (with spectroscopy), multiple MR image slices or a full 3D volume. In practice the variation in PDFF over a liver in many situations (homogeneous liver diseases) can be fairly small and so it would likely be possible to use a single value of PDFF in these simulations of the signals, but maps of PDFF might also be used. It might be necessary to perform image registration of PDFF maps to the other maps when performing the simulation of the signals.

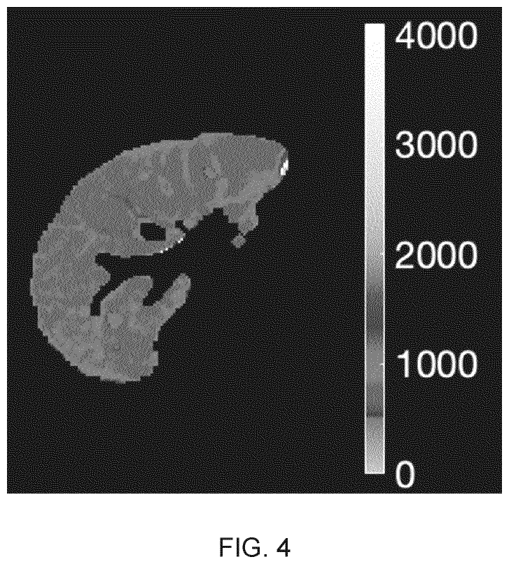

FIG. 4 shows a water T1 map (a parametric map of the water T1) of liver obtained for the original subject, using fat-suppressed NOLLI data acquired on a 1.5 T GE scanner. Fat suppression was used to minimize the influence of fat on the calculated water T1 values. A liver mask was generated based on a machine learning algorithm that replicates the performance of a manually drawn mask using the example embodiment of the invention. This figure shows the expected uniformity in the organ of interest in the subject. As shown, there is no impact of fat in this map as fat is suppressed in the acquisition of these images. The data used to produce this image was acquired on a Siemens®) 1.5 T scanner. Regions containing flowing blood are impacted by flow artefacts in this method. Masking has been used to remove background noise. Various approaches to masking can be used and none are critical to this invention. In this case a mask was generated based on a machine learning algorithm that replicates the performance of a manually drawn mask around the liver, a manual approach could have been used but the machine learning approach is used for reasons of efficiency.

For the LMS acquisition, data were fit using the LMS Discover tool (in Matlab) that has the same general performance characteristics as the LMS Medical Device but has additional flexibility for rapid prototyping exploratory work.

Taking the measurement of iron and PDFF (fat) from the Matlab®) processing and the NOLLI-water T1 map the cT1 was determined that would have been measured had the sample had normal level of iron and had been scanned on a Siemens®) 3 T scanner using the MOLLI method. In this invention, T2* is standardized to 23.1 ms at 3 T for ease of calculation. Other values of T2* may be used for alternative standards.

This was performed by firstly correcting the measured NOLLI-water T1 for the impact of iron, then by calculating the water T1 that the tissue would have if it were at 3 Tesla (rather than the 1.5 T that the data were acquired). The iron correction is performed by determining the iron concentration using the T2* map and the B0 field strength, and then using a known equation. (R1(3 T)=R1₀(3 T)+HIC×0.029 g/mg·s; where R1=1/T1, and HIC is the hepatic iron concentration) to determine the effects on T1 due to the differences in iron concentration from the normal level. In an example embodiment of the invention the field strength correction and iron correction are used to generate a corrected water T1 map, at step 614. In an example embodiment of the invention this will use a forward Bloch simulation. Preferably, the field strength correction is based on modification of a nominal field strength used for the acquisition of the at least three medical inversion recovery MR images. Further preferably, the iron correction corrects for differences in an iron concentration from a normal level using at least one of a T2* map and a B0 field strength.

The determination of the forward Bloch simulation is shown at 650 in FIG. 6. A Bloch simulation is performed at step 652, and provides input to model signals at step 654. From this, a dictionary is built at step 656. The steps will loop over the parameter space (which includes water, T1, T2 and PDFF), and are repeated. The output of the forward Bloch simulation is provided to a dictionary of synthetic MR signal relaxation curve data at step 660. The dictionary is then used for dictionary matching at step 616, where raw data from the dictionary is selected which matches the measured corrected water T1 and PDFF from step 614. Preferably, the simulated MR images are generated using a data from a dictionary of synthetic MR signal relaxation curves. In a preferred example embodiment of the invention the data in the dictionary of synthetic MR signal relaxation curves is selected to match at least one of the corrected water T1 and PDFF for the acquired medical MR images.

Preferably, the forward Bloch simulation has inputs comprising one of more of PDFF value, T2 estimate, water T1 value, and details of the pulse sequence for the scanner used to acquire the medical MR images.

The field correction that is performed at step 612 is based on empirically determined mappings of the impact of field strength on T1 and is evaluated from a group of subjects scanned at each field strength. The output of the liver iron concentration determination from step 636 is, provided at step 612 to be used for the iron correction of the water T1 map, previously generated at step 610. In this example embodiment of the invention the field correction could be performed before or after iron correction. In some example embodiments of the invention a scanner dependent correction may also be performed.

Once this field strength and iron corrected water T1 has been calculated, this value along with the PDFF were used in a Bloch equation of the MOLLI sequence to determine the signals that would be expected if this subject had normal iron levels (in this case represented by a T2* at 3T of 23.1 ms), this standardization is not modified for subject weight, age or sex. If the PDFF was not included in the simulation then this would be a value standardized for a person with normal iron levels, a heart rate of 60 bpm and with no liver fat. The Bloch equation simulation of the MOLLI sequence takes the iron and field strength corrected water T1, the PDFF, and the exact pulse sequence that has been implemented on the reference MRI scanner, for example a Siemens®) 3 T scanner, it starts at time=0 with a fully relaxed magnetization vector (Mz=1, Mx=0, My=0) and for short time increments (typically 50 microseconds) evaluates how the magnetization vector is impacted by the effects of RF pulses, off-resonance effects, spoiling gradients and spin relaxation (T1 and T2). At points in time when the signal would be sampled in the imaging sequence the simulated magnetization vector is recorded. The fat and water signals are simulated separately and combined in proportion to the PDFF.

Preferably, the forward Bloch simulation uses the known characteristics of pulse sequence of the 3 T reference MRI scanner, and this is performed in a simplified manner for each pixel in turn and would yield a series of simulated signals at each pixel. Simulation may be performed using a synthetic heart-rate of 60 beats per minute and for pixels where PDFF>30% the user may fix the PDFF to 30%. These values are chosen as standard parameters, although other values may also be used as standardization parameters. The fat would be simulated using the standard 6-peak fat model that is known to represent hepatic fat. Further, the T2 relaxation of the water would be fixed to the T2 of liver with a normal level of iron. The fat and water signals would be combined using the known concentrations from the PDFF(x,y,z) map (this could be position dependent or a global measurement could be used). The MOLLI sequence collects 7 or more images each at different Inversion Time (TI), which would result in an array of signals S(TI,x,y,z).

Finally, at step 618 these simulated MOLLI signals obtained are fed into a standard LMS cT1 fitting pipeline (with normal iron levels, as iron has already been corrected) that determines the cT1, which is output as a super standardized cT1 at step 620. That is, the resulting S(TI,x,y,z) matrix would be fit at each pixel to yield a map of cT1 (x,y,z). This cT1 should be equivalent to the cT1 derived using the super-standardized MOLLI methods, which is known to be standardized for field strength and MRI vendor. This final fitting step performs a pixel-by-pixel least-squares fit of the function:

$$S ( TI ) = ( A - B exp ( - TI / {T}_{1}^{*} )$$

and determines T1 as:

$$T 1 = T {1}^{*} ( ( B / A ) - 1 )$$

In the usual manner for fitting of MOLLI data, either by building a dictionary of varying A, B and T1* and building fit functions for each of these in a dictionary, and then seeing which one best represents the data (perhaps via a least squares estimate, or comparison of the two curves through choosing the combination with the maximum of the dot product of the normalized data with the normalized dictionary). Alternatively, A, B and T1* can be fit using a iterative search approach (i.e. minimised least squares and Levenberg-Marquart), in practice this fitting is not difficult to perform using standard approaches. Once A, B and T1* are known T1 can be determined. In this case the S(TI) have been generated in a manner to ensure that the resulting T1 is standardized to cT1.his processing yields a standardized cT1 measurement.

It would be expected that there would be some small (˜5%) systematic difference between this modelling approach and the direct MOLLI acquisition approach. There are several sources for these offsets, most obviously Magnetization Transfer effects, but also subtle bias in water T1 mapping. The user would apply a fixed offset to the cT1 for each acquisition pipeline based on comparing human data acquired using the known systems and by this approach. Each pipeline of acquisition (as described above) would need a specific calibration with the goal of these methods delivering the same value for subjects with a cT1 of 825 ms, by modelling for the impact of fat, iron etc. it would be possible to use a single offset per scanner and for the cT1 from different scanners to be reliably standardized across of a range of fat, iron, water T1, etc. This offset might be applied to cT1, but it also might be applied to a different parameter to get the same effect (e.g., water T1).

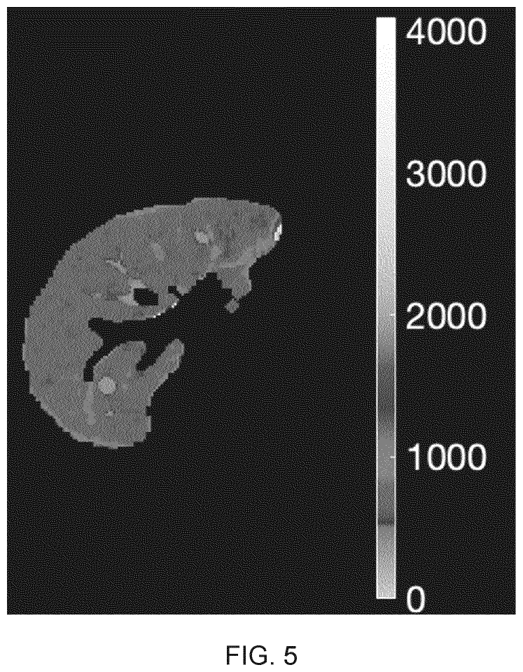

FIG. 5 illustrates a standard cT1 MR image of the liver using the acquisition method of this invention at 1.5 T and mapped into cT1 at 3 T using the described novel approach. In this example of the invention the raw MR data was acquired using a fat-suppressed sequence as shown in FIG. 6 on a 1.5 T GE MRI scanner. Preferably, at least three medical MR images of a subject were acquired and analysed to determine a water T1 map. A field strength correction and an iron correction were applied to the water T1 to generate a corrected water T1 map. One of more simulated MR images were generated based on the water T1 map, and there where then fitted to determine the standard cT1 MR image described above. As described previously, the simulated MR images are provided to a cT1 fitting pipeline to determine the corrected cT1 image. The cT1 map shown illustrates the mapped cT1 values, corresponding to the standard MOLLI sequence on a 3 T Siemens®) Prisma scanner. The cT1 map derived from the data with ROI positions shown for the subject. Data from a Siemens®) 1.5 T scanner. 3×ROI=629, 624, 663 ms. These are shown as highlighted circles in the image. The Pooled median in the image for cT1=640+/−51 ms. Typically the pooled median is used, but other metrics such as mean, median, pooled mean may also be used, however pooled median is preferred as this is more robust.

Mapping algorithms are only applicable for regions within the liver, regions outside the liver are not correctly mapped.

In the example embodiment of the invention as described the image processing could be performed at different dimensions. For example the method of the invention it could be applied at the level of a single large voxel (as in spectroscopy) or over a single region of interest, it could be applied on a pixel by pixel basis over a 2D image, or it could be applied on a pixel by pixel basis over an entire 3D volume. Preferably, the most likely use cases would be to generate cT1 maps in a single 2D slice, in multiple 2D slices or over a 3D volume.

This novel acquisition and processing pipeline is able to deliver synthetic MR signal relaxation curves that demonstrate similar spatial uniformity to the standard LMS MOLLI approach. The quantitative values determined with the novel acquisition and processing pipeline yield values that are consistent with the standard LMS MOLLI approach. Therefore, the novel acquisition and processing pipeline provides a mechanism to deliver a surrogate approach to LMS MOLLI cT1. A further advantage of this invention is that a cT1 map can be obtained from any MRI scanner, irrespective of the magnet strength of the scanner, or the company who have produced the scanner. In addition, the cT1 map obtained using the invention maybe more reproducible, or have a higher spatial resolution, or possess some other characteristics than meant the synthetic cT1 obtained with the invention is superior to cT1 as determined with the prior art MOLLI acquisition technique.

The present invention has been described with reference to the accompanying drawings. However, it will be appreciated that the present invention is not limited to the specific examples herein described and as illustrated in the accompanying drawings. Furthermore, because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

The invention may be implemented in a computer program for running on a computer system, at least including code portions for performing steps of a method according to the invention when run on a programmable apparatus, such as a computer system or enabling a programmable apparatus to perform functions of a device or system according to the invention.

A computer program is a list of instructions such as a particular application program and/or an operating system. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system. The computer program may be stored internally on a tangible and non-transitory computer readable storage medium or transmitted to the computer system via a computer readable transmission medium. All or some of the computer program may be provided on computer readable media permanently, removably or remotely coupled to an information processing system.

A computer process typically includes an executing (running) program or portion of a program, current program values and state information, and the resources used by the operating system to manage the execution of the process. An operating system (OS) is the software that manages the sharing of the resources of a computer and provides programmers with an interface used to access those resources. An operating system processes system data and user input, and responds by allocating and managing tasks and internal system resources as a service to users and programs of the system.

The computer system may for instance include at least one processing unit, associated memory and a number of input/output (I/O) devices. When executing the computer program, the computer system processes information according to the computer program and produces resultant output information via I/O devices.

In the foregoing specification, the invention has been described with reference to specific examples of embodiments of the invention. It will, however, be evident that various modifications and changes may be made therein without departing from the scope of the invention as set forth in the appended claims. Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality. Any arrangement of components to achieve the same functionality is effectively ‘associated’ such that the desired functionality is achieved. Hence, any two components herein combined to achieve a particular functionality can be seen as ‘associated with’ each other such that the desired functionality is achieved, irrespective of architectures or intermediary components. Likewise, any two components so associated can also be viewed as being ‘operably connected,’ or ‘operably coupled,’ to each other to achieve the desired functionality.

Furthermore, those skilled in the art will recognize that boundaries between the above-described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The specifications and drawings are, accordingly, to be regarded in an illustrative rather than in a restrictive sense. Unless stated otherwise, terms such as ‘first’ and ‘second’ are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. A method of analysing magnetic resonance (MR) images comprising:
acquiring at least three medical MR images that are inversion recovery images of a subject and acquiring an additional MR image of the subject acquired without the use of an inversion pulse;
analysing the at least three medical MR images and the additional MR image to determine a water T1 map, and applying a field strength correction and an iron correction to the water T1 map to generate a corrected water T1 map;
generating multiple simulated MR images based on the corrected water T1 map and a proton density fat fraction PDFF map for the at least three medical MR images; and
fitting a model function to the multiple simulated MR images to determine a standardized corrected T1 cT1 image for the subject.

2. A method as claimed in claim 1 wherein the standardized cT1 image is a cT1 image corrected for a reference image acquired on a reference MRI scanner for a subject with normal iron levels.

3. A method as claimed in claim 2 wherein the simulated MR images are generated using data from a dictionary of synthetic MR signal relaxation curves.

4. A method as claimed in claim 3 wherein the data in the dictionary of synthetic MR signal relaxation curves is selected to match at least one of: the corrected water T1 map and a proton density fat fraction, PDFF, map, for the acquired medical MR images.

5. A method according to claim 3 wherein each of the at least three medical MR images comprise pairs of images with the same inversion time.

6. A method as claimed in claim 1 wherein each successively acquired one of the at least three medical MR images has a longer inversion time than the previously acquired one of the at least three medical MR images.

7. A method according to claim 6 wherein the minimum value for the inversion time of the first medical MR image is between 0.010-1.0 seconds.

8. A method according to claim 2 wherein the at least three medical MR images comprises eight medical MR images.

9. A method according to claim 1 wherein the at least three medical MR images are acquired so that there will be redundant MR images.

10. A method as claimed in claim 1 wherein the at least three of the medical MR images are acquired using a single shot acquisition.

11. A method as claimed in claim 10 wherein the single shot acquisition comprises at least one of: EPI or single shot fast echo.

12. A method according to claim 2 wherein the field strength correction and iron correction to generate the corrected water T1 map use a forward Bloch simulation.

13. A method according to claim 12 wherein the field strength correction is based on modification of a nominal field strength used for the acquisition of the at least three medical MR images.

14. A method according to claim 13 wherein the iron correction corrects for differences in an iron concentration from a normal level using at least one of a T2* map and a B0 field strength.

15. A method according to any of claim 14 wherein the forward Bloch simulation has inputs comprising one of more of PDFF value, T2* value, water T1 value, a pulse sequence for a MRI scanner used to acquire the medical MR images.

16. A method as claimed in claim 1 wherein the analysis of the at least three medical MR images results in a composite image.

17. A method as claimed in claim 16 wherein the water T1 map is determined for the composite image.

18. A method according to claim 1 wherein the at least three medical MR images are acquired with use of a single inversion pulse that is an adiabatic pulse.

19. A method according to claim 1 comprising the steps of acquiring further medical MR images immediately before or after the acquisition of the at least three medical MR images.

20. A method according to claim 19 wherein the further medical MR images are multi-echo spoiled gradient echo acquisition images.

21. (canceled)
